(19) United States
(12) Patent Application Publication
(10) Pub. No.: US 2004/0228252 A1
(43) Pub. Date: Nov. 18, 2004

(54) Method of detecting binary data and apparatus therefor

(75) Inventors: Hyun-soo Park, Seoul (KR); Jae-seong Shim, Seoul (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-Si (KR)

(21) Appl. No.: 10/814,789

(22) Filed: Apr. 1, 2004

(30) Foreign Application Priority Data
Apr. 29, 2003 (KR) 2003-27074

(51) Int. Cl. G11B 3/00; H03M 1/12

(52) U.S. Cl. 369/59.17; 341/155

(57) ABSTRACT

A method and apparatus detecting binary data from a signal read from an optical recording medium are provided. The apparatus detecting binary data includes a first signal processor nonlinearly converting the input signal based on the result of comparing an absolute value and a predetermined critical value of the input signal and a second signal processor detecting binary data from the nonlinearly converted signal.

### CROSS-REFERENCE TO RELATED APPLICATIONS

This application claims the priority of Korean Patent Application No. 2003-27074, filed on Apr. 29, 2003, in the Korean Intellectual Property Office, the disclosure of which is incorporated herein in its entirety by reference.

### BACKGROUND OF THE INVENTION

1. Field of the Invention

The present invention relates to a method and apparatus which detect binary, and more particularly, to a method and apparatus which detect binary data from a signal that is read from an optical disk.

2. Description of the Related Art

Reproduction data recorded as a binary signal on an information storage medium such as an optical disk is executed via projecting laser beams onto the surface of the optical disk and reading a reflected waveform of the laser beam. In this process, the signal that is read from the disk is a radio frequency (RF) signal. Due to the features of a disk and optics, the RF signal read from the disk has the characteristics of an analog signal, even though a signal recorded on the disk contains binary data.

Therefore, a binarization medium and a phase locked loop (PLL) are required in order to convert the RF signal having the characteristics of an analog signal to a digital signal containing binary data. The binarization medium may be embodied in several forms, however a viterbi decoder in which a binary signal with little error can be obtained, is most widely used.

FIG. 1 shows an apparatus for detecting binary data with a conventional data reproducing device. Referring to FIG. 1, the conventional data reproducing device includes an analog-to-digital A/D converter 110, a DC offset canceller 120, an adder 130, an equalizer 140, a viterbi decoder 150, and a PLL 160.

The A/D converter 110 converts an analog signal or an RF signal that is read from an optical recording medium to a digital signal using a predetermined sampling cycle. The DC offset canceller 120 extracts a DC offset from digital data output from the converter 110. The adder 130 uses the DC offset output from the DC offset canceller 120 to cancel the offset of the digital data output from the A/D converter 110 and outputs the digital data without the DC offset. The equalizer 140 compensates for an error included in digital data without the DC offset and is used to correct an error in a device such as a hard disc drive. The viterbi decoder 150 compensates for an asymmetric component included in a signal output from the equalizer 140. An example of a signal processing method using the viterbi decoder is a partial response maximum likelihood (PRML) method. A phase locked signal generated by the PLL 160 is used as a clock signal in the other circuits in FIG. 1.

The recording density of optical recording media such as optical discs is constantly being increased. As recording density increases, the quality of reproduced signals becomes poorer, and thus an error exceeding a signal binarization level occurs. In this case, conventional data detecting methods also produce errors even if the viterbi decoder is used due to poor data detection.

### SUMMARY OF THE INVENTION

The present invention provides an apparatus for detecting binary data from a signal read from an optical recording medium and the apparatus includes a first signal processor nonlinearly converting an input signal based on the result of comparing the absolute value of the input signal and a predetermined critical value of the input signal, and a second signal processor detecting binary data from the nonlinearly converted signal.

In accordance with an aspect of the invention the first signal processor saturates the input signal by the predetermined critical value when the absolute value of the input signal is bigger than the critical value of the input signal and outputs the input signal when the absolute value of the input signal is smaller than the critical value.

In another aspect of the invention, the first signal processor outputs the difference of the absolute value at the input signal and the critical value when the absolute value of the input signal is bigger than the critical value and output zero when the absolute value of the input signal is smaller than the critical value.

In another aspect of the invention, the first signal processor includes a digital filter that yields the result of the following equation, wherein, | | indicates an absolute value, the braces and their contents become one if a conditional expression is true and zero if a conditional expression contained therein is false, x is the input signal, and k is a predetermined value ranging from zero to a positive real number.

y=x×{|x|≦k}+k(−1)^{{|x|≦0}×}{|x|>k}

In another aspect of the invention the first signal processor includes a digital filter that yields the result of the following equation. In the equation, | | indicates an absolute value, the braces and their contents become one if a conditional expression is true and zero if a conditional expression contained therein is false, x is the input signal, and k is a predetermined value ranging from zero to a positive real number.

y=x×{|x|>k}+k(−1)^{{|x|>0}×}{|x|>k}

In another aspect of the invention, the first signal processor is only comprised of a digital filter.

In another aspect of the invention, the first signal processor uses a finite impulse response (FIR) filter in front of the digital filter.

In another aspect of the invention, the first signal processor uses the FIR filter behind the digital filter.

In another aspect of the invention the first signal processor uses the FIR filter in front of and behind the digital filter.

In another aspect of the invention, the first signal processor uses the FIR filter that is connected to the digital filter in parallel.

In another aspect of the invention, the second signal processor is a viterbi decoder and the viterbi decoder is one of the three partial response (PR) polynomial methods, that is a PR (a,b,a) method, a PR (a,b,b,a,) method, or a PR (a,b,c,b,a) method.

According to an aspect of the present invention, there is provided a method of detecting binary data from a signal read from an optical recording medium, including nonlinearly converting the input signal based on the result of comparing the absolute value of the input signal and a predetermined critical value; and detecting binary data from the nonlinearly converted signal.

According to another aspect of the present invention, there is provided a computer readable medium having embodied thereon a computer program for a method of detecting binary data from a signal read from an optical recording medium, including nonlinearly converting the input signal based on the result of comparing the absolute value and a predetermined critical value; and detecting binary data from the nonlinearly converted signal.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the exemplary embodiments taken in conjunction with the accompanying drawings in which:

FIG. 1 is a block diagram of an apparatus for detecting binary data in a conventional data reproducing device;

FIG. 2 is a block diagram of a data reproducing device having a binary data detector according to an embodiment of the present invention;

FIG. 3 is a block diagram of a binary data detector according to an embodiment of the present invention;

FIG. 4 is a block diagram illustrating a nonlinear converter shown in FIG. 3 according to an embodiment the present invention;

FIG. 5 is a drawing illustrating a finite impulse response (FIR) filter used in the nonlinear converter according to an embodiment of the present invention;

FIGS. 6A-6D are drawings illustrating the operation of the nonlinear filter shown in FIG. 4 according to an embodiment of the present invention;

FIG. 7 is a block diagram of a binary data detector according to an embodiment of the present invention;

FIG. 8 is a block diagram of a binary data detector according to an embodiment of the present invention;

FIG. 9 is a block diagram of a binary data detector according to an embodiment of the present invention;

FIG. 10 is a block diagram of a binary data detector according to an embodiment of the present invention;

FIG. 11 is a block diagram of a binary data detector according to an embodiment of the present invention;

FIG. 12 is a drawing illustrating an embodiment of a FIR filter used in a nonlinear converter according to an embodiment of the present invention; and

FIG. 13 is a block diagram of a binary data detector according to an embodiment of the present invention.

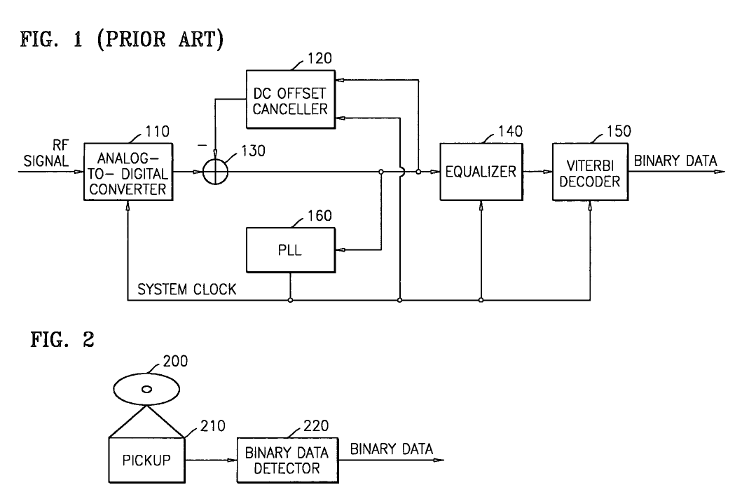

### DETAILED DESCRIPTION OF THE EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

FIG. 2 is a block diagram illustrating an exemplary embodiment using a binary data detector according to an embodiment of the present invention.

The data reproducing device shown in FIG. 2 is a device reproducing a disk 200 recorded as a reproducible data structure, and includes a pickup 210 and a binary data detector 220. The pickup 210 irradiates a laser beam to a surface of the disk 200, receives the laser beam reflected from the surface of the disc 200, and outputs a radio frequency (RF) signal. The binary data detector 220 detects binary data from the RF signal.

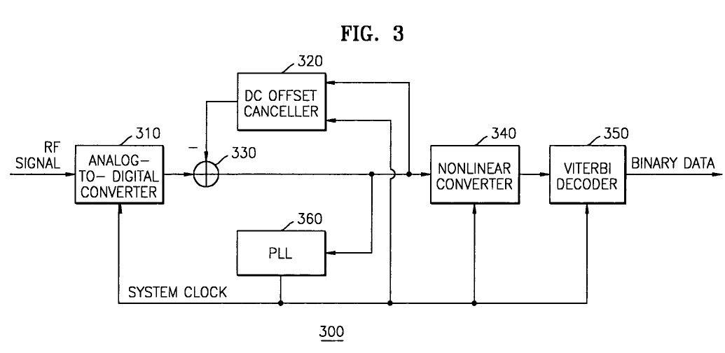

FIG. 3 displays an apparatus detecting binary data according to an embodiment of the present invention. Referring to FIG. 3, the binary data detector 300 includes an analog-to-digital A/D converter 310, a DC offset canceller 320, an adder 330, a nonlinear converter 340, a viterbi decoder 350, and a phase locked loop (PLL) 360.

The A/D converter 310 digitally converts an analog signal read from an optical recording medium, or a RF signal using a predetermined sampling cycle. The DC offset canceller 320 cancels a DC offset included in sampling data output from the A/D converter 310. The adder 330 subtracts the DC offset output from the DC offset canceller 320 from the digital data from the analog-to-digital A/D converter 310 and outputs the subtracted digital data with no DC offset.

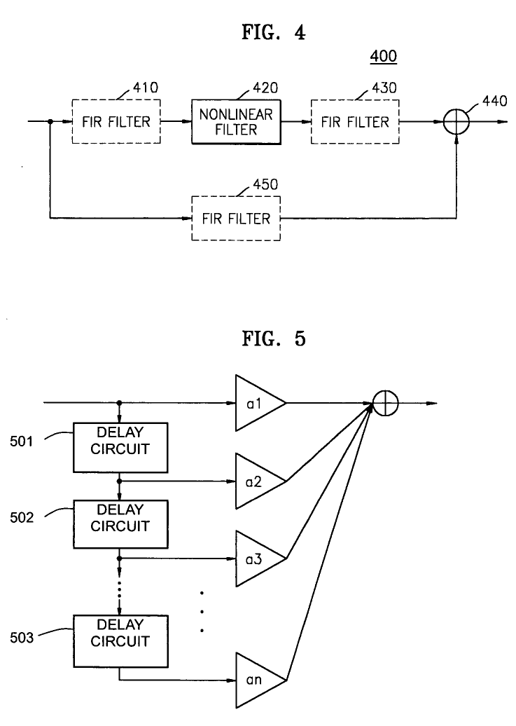

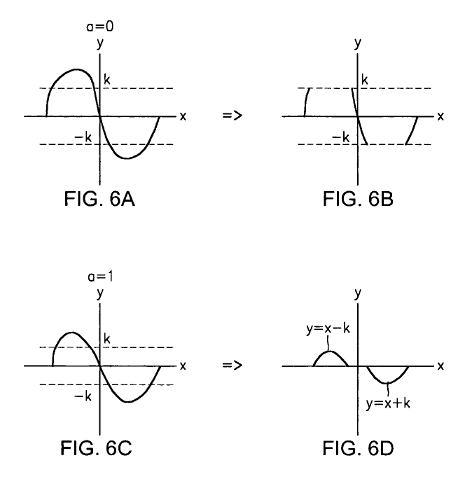

The nonlinear converter 340 changes the shape of the input signal using a nonlinear function and forcibly saturates values of a waveform beyond a predetermined value or removes values of the waveform below a predetermined value. The nonlinear converter 340 will be explained later with reference to FIGS. 4 and 6A-6D. The signal output from the nonlinear converter 340 is input into the viterbi decoder 350.

The viterbi decoder 350 converts the signal passing the nonlinear converter 340 to binary data based on a predetermined method and outputs the same signal. An example of a signal processing method using the viterbi decoder is a partial response maximum likelihood (PRML) method. According to this embodiment, the viterbi decoder uses one of the three partial response (PR) polynomial methods, that is a PR (a,b,a) method, a PR (a,b,b,a) method, or a PR (a,b,c,b,a) method.

PLL 360 generates a clock signal provided to a binary data detector 300, using a signal output from the A/D converter 310.

FIG. 4 is a block diagram illustrating the nonlinear converter shown in FIG. 3, according to an embodiment of the present invention. Referring to FIG. 4, a nonlinear converter 400 has three finite impulse response (FIR) filters 410, 430, and 450, a nonlinear filter 420, and an adder 440.

In the nonlinear converter 400, the FIR filter effectively operates the nonlinear converter 400 by changing the frequency characteristics of the input signal. However, if the frequency characteristics of the input signal can be satisfied by using only a nonlinear filter, the FIR filter may be omitted. Therefore, one or all of the FIR filters 410, 430, and 450 may be omitted depending on the application. In addition, the number of taps forming FIR filters 410, 430, 450 can be differentiated. The FIR filters will be explained in more detail referring to FIG. 5.

FIG. 5 illustrates the FIR filters 410, 430, and 450 shown in FIG. 4, according to an embodiment of the present invention. Referring to FIG. 5, an FIR filter that is used to change the frequency characteristics of the input signal, includes a plurality of delay circuits 501, 502, 503 that delay the signal input by a clock cycle, for example a system clock, a plurality of multipliers a1, a2, a3, . . . an that multiply the delayed signal value by a predetermined value, and an adder that adds together the outputs of the plurality of multipliers. The value output from each multiplier is a real number including zero.

Now, the nonlinear filter 420 shown in FIG. 4 will be described referring to equation (1) below and FIGS. 6A-6D. Equation 1 shows an example of a nonlinear function used in the nonlinear filter according to an embodiment of the present invention.

y=x×({a=0}×{|x|≦k}+{a=1}×{|x|>k})

+k(−1)^{({a=0})×{|x|≧0})×({a=0}×{|x|>0})×}({a=0}×{|x|>k}+ (1)

Here, | | indicates an absolute value, the braces and their contents become one if a conditional expression is true and zero if a conditional expression is false, x is the input signal which is a real number, and k is a nonlinear critical value ranging from zero to a positive real number. In addition, a is a value indicating a different kind of nonlinear filter.

Values of equation (1) corresponding to different kinds of nonlinear filters and varying amplitudes of the input signal are as follows:

a=0, if |x|>k and x>0, y=k

a=0, if |x|>k and x<0, y=−k

a=0, if |x|≦k, y=x

a=1, if |x|>k and x>0, y=x−k

a=1, if |x|>k and x<0, y=x+k

a=1, if ||≦k, y=0

FIGS. 6A-6D represent equation 1 for different kinds of nonlinear filters and different amplitudes of input signal.

FIGS. 6A and 6B indicate the operation of the nonlinear filter if a is zero. In this case, the nonlinear filter saturates the input signal if the absolute value of the input signal x is bigger than a critical value k and outputs the input signal if the absolute value of the input signal x is smaller than the critical value k.

FIGS. 6C and 6D show the operation of the nonlinear filter if a is 1. In this case, the nonlinear filter outputs a signal representing the difference between the input signal x and the critical value k if the absolute value of the input signal x is larger than the critical value k and the input signal x is greater than 0. The nonlinear filter outputs a signal representing the summation of the input signal x and the critical value k if the absolute value of the input signal x is larger than the critical value k and the input signal x is less than 0. The nonlinear filter outputs 0 if the absolute value of the input signal x is less than or equal to the critical value k.

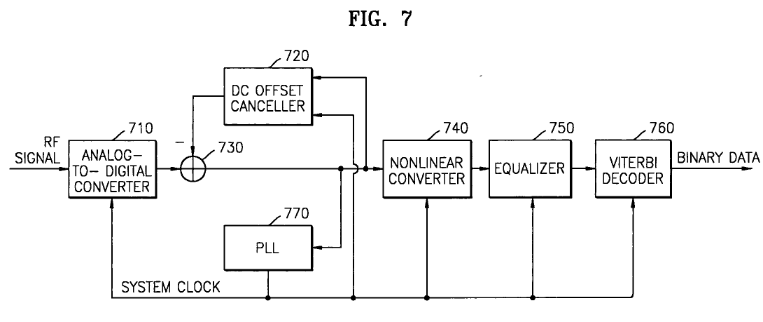

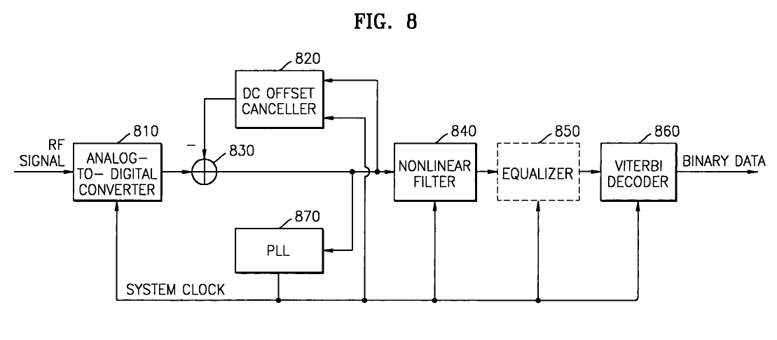

FIG. 7 shows an apparatus for detecting binary data according to an embodiment of the invention. Referring to FIG. 7, the apparatus detecting binary data includes an analog-to-digital converter 710, a DC offset canceller 720, an adder 730, a nonlinear converter 740, an equalizer 750, a viterbi decoder 760 and a phase locked loop (PLL) 770.

A detailed explanation of the analog-to-digital converter 710, the DC offset canceller 720, the adder 730, the viterbi decoder 760 and the PLL 770 will be omitted because the above components perform the same operation as their counterparts in FIG. 3.

In FIG. 7, a signal output from the nonlinear converter 740 is input into the equalizer 750. The equalizer 750 converts the input signal to a signal having an optimal condition with respect to the viterbi decoder 760. The equalizer 750 is a kind of FIR filter used to make the channel characteristics be at an optimal level.

For example, assuming a viterbi decoder has a type of (a,b,a), the optimal condition is when the input signal has one of the following outputs:

when a,b,a=0,0,0: 0+0+0=0

a,b,a=0,0,1 0+0+a=a

a,b,a=0,1,0 0+b+0=b

a,b,a=0,1,1 0+b+a=a+b

a,b,a=1,0,0 a+0+0=a

a,b,a=1,0,1 a+0+a=2a

a,b,a=1,1,0 a+b+0=a+b

a,b,a=1,1,1 a+b+a=2a+b

Assuming, for example, that a=1 and b=2, when an input signal has a value such as 0, 1, 2, 3 and 4, an input signal has an optimal condition and will be properly decoded. However, when an input signal has a value such as 0.1, 0.5, 1.3 or 1.8, the input signal does not have an optimal condition and will not be decoded correctly due to noise. Thus, the equalizer 750 converts the input signal having noise (e.g., 0.1, 0.5, 1.3, and 1.8) into a signal having an optimal condition (e.g., 0, 1, 2, 3 and 4).

A signal output from the equalizer 750 is input into the viterbi decoder 760.

The viterbi decoder 760 converts the signal output from the equalizer 750 to binary data by a predetermined method and outputs the signal.

FIG. 8 is a drawing of an example of an apparatus detecting binary data to which the nonlinear converter displayed in FIG. 4 is applied, according to another embodiment of the present invention. A detailed explanation on an analog-to-digital converter 810, a DC offset canceller 820, an adder 830, an equalizer 850, and a viterbi decoder 860 displayed in FIG. 8 will be omitted because the above components perform the same operation as the counterparts displayed in FIG. 7.

If the type of nonlinear filtering in the nonlinear filter 840 is as shown in FIG. 6B, where a=0, the nonlinear filter 840 outputs a nonlinear critical value if an absolute value of the signal input from the analog-to-digital converter 810 is bigger than a nonlinear threshold.

That is, it is possible to prevent poor operation of the viterbi decoder 860 and to enhance its performance when a value that is not required by the viterbi decoder 860 is input, by using the nonlinear filter 840 through a process of forceful saturation.

If a run length limited (RLL) code, namely a RLL code having a run length ranging from a minimum level d (=1) to a maximum level k (=7) and the PR (a,b,a) type viterbi decoder are used and four levels input by the viterbi decoder are included, effective decoding can be obtained. The reason is that the input signal can be changed to be suitable for the four levels when using a nonlinear function.

Furthermore, if the type of nonlinear filtering in the nonlinear filter 840 is a=0, the nonlinear filter 840 outputs the input signal if the absolute value of the signal input from the analog-to-digital converter 810 is smaller than the critical value.

In addition, if the type of nonlinear filtering in the nonlinear filter 840 is a=1, the nonlinear filter 840 outputs the difference of the absolute value at the input signal and the critical value when the absolute value of the input signal is bigger than the nonlinear critical value and outputs zero when the absolute value of the input signal is smaller than the nonlinear critical value.

The signal having an optimal condition can be input into the viterbi decoder 860 using the equalizer 850 between the nonlinear filter 840 the viterbi decoder 860. However, when using a nonlinear converter such as the nonlinear filter 840 in the present embodiment, the equalizer 850 is not always necessary since it is possible that the signal input can be converted to a level suitable for the viterbi decoder 860 using an RLL code.

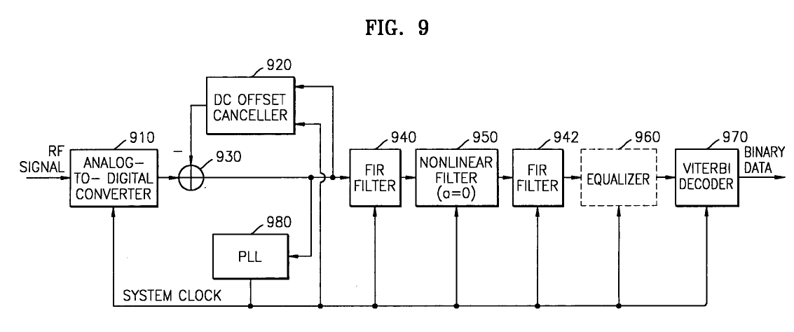

FIG. 9 is a block diagram of an example of an apparatus detecting binary data, to which applies the nonlinear converter displayed in FIG. 4, according to another embodiment of the present invention. A detailed explanation of an analog-to-digital converter 910, a DC offset canceller 920, an adder 930, an equalizer 960, a viterbi decoder 970 will be of the among components shown in FIG. 9 because these components perform the same operation as the counterparts shown in FIGS. 3 and 7.

Referring to FIG. 9, FIR filters 940 and 942 are used in front of and behind the nonlinear filter 950. In this case, effective conversion of the input signal by changing the frequency characteristics of the input signal is obtained. Thus, capability of the viterbi decoder is enhanced.

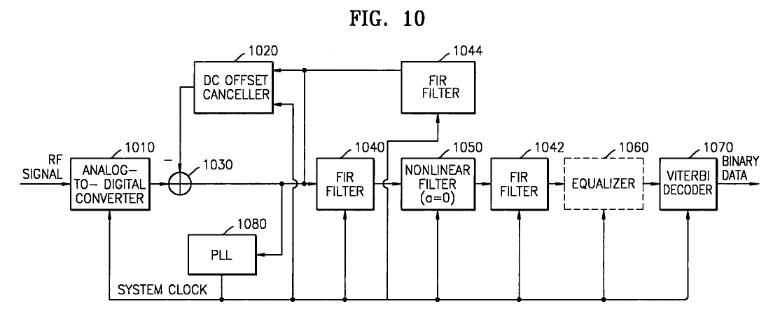

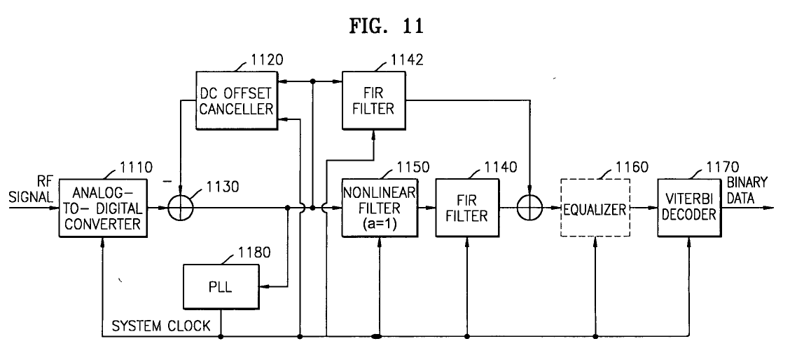

FIG. 10 is a block diagram of an example of an apparatus detecting binary data, to which the nonlinear converter displayed in FIG. 4 applies, according to an embodiment of the present invention. A detailed explanation of an analog-to-digital converter 910, a DC offset canceller 920, an adder 930, an equalizer 960, and a viterbi decoder 970 of the components shown in FIG. 10 will be omitted because these components perform the same operation as the counterparts shown in FIGS. 3 and 7.

Referring to FIG. 10, FIR filters 1040, 1042, and 1044 are used in front of and behind the nonlinear filter 1050. In this case, effective conversion of the input signal by changing the frequency characteristics of the input signal is obtained. Thus, the capability of the viterbi decoder is enhanced.

FIG. 11 is a drawing of an example of an apparatus detecting binary data, to which the nonlinear converter displayed in FIG. 4 applies, according to an embodiment of the present invention. A detailed explanation on an analog-to-digital converter 1110, a DC offset canceller 1120, an adder 1130, an equalizer 1160, and a viterbi decoder 1170 of the components shown in FIG. 10 will be omitted because these components perform the same operation as the counterparts shown in FIGS. 3 and 7.

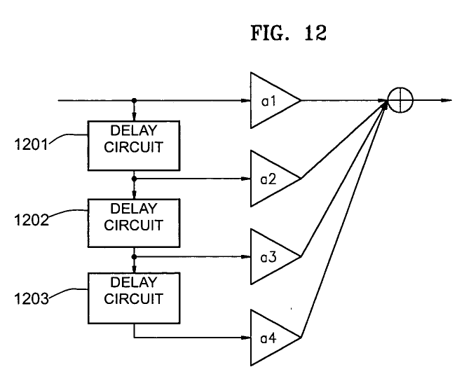

Referring to FIG. 11, FIR filters 1140 and 1142 are used in front of and behind the nonlinear filter 1150, if a=1. In this case, effective conversion of the input signal by changing the frequency characteristics of the input signal is obtained. Thus, capability of the viterbi decoder is enhanced. If a=1, the FIR filter 1140 connected behind a nonlinear function to obtain high quality characteristics, is formed to have a filter coefficient 1,0,0,1 or the characteristics of frequency of cosine conversion on three taps as shown in FIG. 12.

FIG. 12 shows an example of the FIR filter 1140 displayed in FIG. 11, according to an embodiment of the present invention. The FIR filter includes a plurality of delay circuits 1201, 1202, 1203 that delay the signal input by a clock cycle, for example a system clock, a plurality of multipliers a1, a2, a3, . . . an that multiply the delayed signal value by a predetermined value, and an adder that adds together the outputs of the plurality of multipliers. Here, for example multipliers a1, a2, a3 and a filter coefficient a4 are 1, 0, 0, 1, respectively.

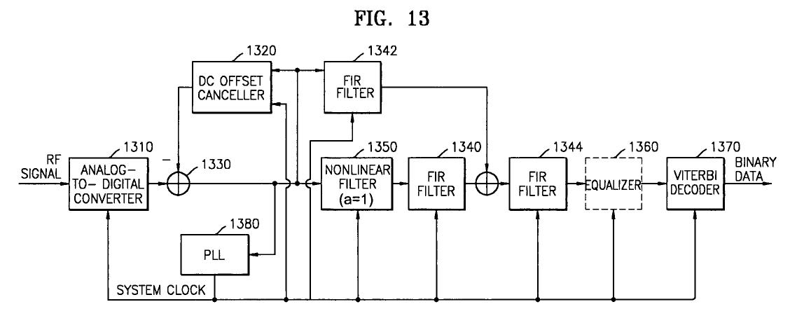

FIG. 13 is a block diagram of an example of an apparatus detecting binary data, to which applies the nonlinear converter displayed in FIG. 4, according to an embodiment of the present invention. A detailed explanation on an analog/digital converter 1310, a DC offset canceller 1320, an adder 1330, an equalizer 1360, and a viterbi decoder 1370 of the components displayed in FIG. 13 will be omitted because these components perform the same operation as the counterparts displayed in FIG. 3 and FIG. 7.

Referring to FIG. 13, FIR filters 1340, 1342, and 1344 are used in front of and behind the nonlinear filter 1350, if a=1. In this case, a more effective conversion of the input signal by changing characteristics of frequency of a signal passing the nonlinear filter 1350 and input into the viterbi decoder 1370 can be obtained. Thus, the capability of the viterbi decoder can be enhanced. If a=1, the FIR filter 1340 connected behind a nonlinear filter 1350 to obtain high quality characteristics, is formed to have a filter coefficient 1,0,0,1 or the characteristics of frequency of cosine conversion on three taps as shown in FIG. 12.

As a result, a method and apparatus detecting binary data allows the signal to be corrected via the nonlinear converter and to reduce errors in detecting data by inputting a corrected signal via the nonlinear converter to the viterbi decoder. Accordingly, capability of a reproducing device reproducing data recorded in an optical recording medium is enhanced, and thus a more reliable optical disk device is provided.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An apparatus detecting binary data from an input signal read from an optical recording medium, the apparatus comprising:
a first signal processor nonlinearly converting the input signal based on a result of comparing an absolute value of the input signal and a predetermined critical value; and
a second signal processor detecting binary data from the nonlinearly converted signal.

2. The apparatus of claim 1, wherein the first signal processor saturates the input signal by the predetermined critical value when the absolute value of the input signal is bigger than the predetermined critical value and outputs the input signal when the absolute value of the input signal is smaller than the predetermined critical value.

3. The apparatus of claim 1, wherein the first signal processor outputs a difference of the absolute value of the input signal and the critical value when the absolute value of the input signal is bigger than the critical value and outputs zero when the absolute value of the input signal is smaller than the critical value.

4. The apparatus of claim 2, wherein the first signal processor includes a digital filter that yields the result of the following equation:
y=x×{|x|≦k}+k(−1)^{{|x|≦0}×}{|x|>k}
wherein | | indicates an absolute value, the braces and their contents become one if a conditional expression contained therein is true and zero if a conditional expression contained therein is false, x is the input signal, and k is a predetermined value ranging from zero to a positive real number.

5. The apparatus of claim 3, wherein the first signal processor includes a digital filter that yields the result of the following equation:
y=x×{|x|>k}+k(−1)^{{|x|>0}×}{|x|>k}
wherein | | indicates an absolute value, the braces and their contents become one if a conditional expression contained therein is true and zero if a conditional expression contained therein is false, x is the input signal, k and is a predetermined value ranging from zero to a positive real number.

6. The apparatus of claim 4, wherein the first signal processor is a digital filter.

7. The apparatus of claim 5, wherein the first signal processor is a digital filter.

8. The apparatus of claim 4, wherein the first signal processor comprises a finite impulse response (FIR) filter in front of the digital filter.

9. The apparatus of claim 5, wherein the first signal processor comprises an FIR filter in front of the digital filter.

10. The apparatus of claim 4, wherein the first signal processor comprises an FIR filter behind the digital filter.

11. The apparatus of claim 5, wherein the first signal processor comprises an FIR filter behind the digital filter.

12. The apparatus of claim 4, wherein the first signal processor comprises FIR filters, respectively, in front of and behind the digital filter.

13. The apparatus of claim 5, wherein the first signal processor comprises FIR filters, respectively, in front of and behind the digital filter.

14. The apparatus of claim 4, wherein the first signal processor comprises an FIR filter that is connected to the digital filter in parallel.

15. The apparatus of claim 5, wherein the first signal processor comprises an FIR filter that is connected to the digital filter in parallel.

16. The apparatus of claim 1, wherein the second signal processor is a viterbi decoder and the viterbi decoder uses one of three methods, that is a PR (a,b,a) method, a PR (a,b,b,a,) method, and a PR (a,b,c,b,a) method.

17. The apparatus of claim 16, wherein the viterbi decoder uses an equalizer that adjusts the frequency characteristics of the input signal.

18. A method of detecting binary data from an input signal read from an optical recording medium, the method comprising:
converting the input signal nonlinearly based on a result of comparing an absolute value of the input signal and a predetermined critical value; and
detecting binary data from the nonlinearly converted signal.

19. The method of detecting binary data of claim 18, wherein the converting the input signal nonlinearly further comprises:
saturating the input signal when the absolute value of the input signal is bigger than the predetermined critical value and outputting the input signal when the absolute value of the input signal is smaller than the predetermined critical value thereof.

20. The method of detecting binary data of claim 18, wherein the converting the input signal nonlinearly further comprises:
outputting the difference between the absolute value of input signal and the critical value when the absolute value of the input signal is bigger than the predetermined critical value, and outputting zero when the absolute value of the input signal is smaller than the predetermined critical value.

21. The method of detecting binary data of claim 18, wherein the converting the input signal nonlinearly is executed according to the following equation:
y=x×{|x|≦k}+k(−1)^{{|x|≦0}×}{|x|>k}
wherein | | indicates an absolute value, the braces and their contents become one if a conditional expression contained therein is true and zero if a conditional expression contained therein is false, x is the input signal, and k is a predetermined value ranging from zero to a positive real number.

22. The method of detecting binary data of claim 18, wherein the converting the input signal nonlinearly is executed according to the following equation:
y=x×{|x|>k}+k(−1)^{{|x|>0}×}{|x|>k}
wherein | | indicates the absolute value, the braces and their contents become one if the conditional expression contained therein is true and zero if the conditional expression contained therein is false, x is the input signal, and k is the predetermined critical value ranging from zero to a positive real number.

23. A computer readable medium having embodied thereon a computer program of a method of detecting binary data from a signal read from an optical recording medium, the method comprising;
converting the input signal nonlinearly based on the result of comparing the absolute value of the input signal and a predetermined critical value; and
detecting binary data from the nonlinearly converted signal.

24. The computer readable medium of claim 23, wherein the converting the input signal nonlinearly further comprises:
saturating the input signal by the predetermined critical value when the absolute value of the input signal is bigger than the critical value and outputting the input signal when the absolute value of the input signal is smaller than the critical value.

25. The computer readable medium of claim 23, wherein nonlinearly converting the input signal further comprises:
outputting the difference between the absolute value of the input signal and the critical value when the absolute value of the input signal is bigger than the critical value and output zero when the absolute value of the input signal is smaller than the critical value.
